(19) United States
(12) Patent Application Publication
(10) Pub. No.: US 2008/0076253 A1
(43) Pub. Date: Mar. 27, 2008

(54) Adhesive Sheet,Semiconductor Device,and Process for Producing Semiconductor Device

(76) Inventor: Hiroshi Fukada, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/576,267

(22) PCT Filed: Sep. 30, 2004
(86) PCT No.: PCT/JP04/14356

§ 371 Date: Mar. 29, 2007

(51) Int. Cl. H01L 21/461

(52) U.S. Cl. 438/692; 257/E21.483

(57) ABSTRACT

In the polishing head of a CMP device, the diaphragm which includes an elastic body film is fixed to a carrier plate with the diaphragm stop ring which includes a metallic material. The screw stop of the retaining ring which includes a resin material is done to this diaphragm stop ring with a screw from a lower part. A groove is formed in the under surface of a retaining ring, and the screw hole for doing the screw stop of the retaining ring is formed in the groove. By pressurizing the space sealed by a diaphragm, membrane, etc., a semiconductor wafer is pushed against a polishing pad via membrane, and CMP treatment of the semiconductor wafer is done.

The present application claims priority from PCT application PCT/JP2004/014356 filed on Sep. 30, 2004, the content of which is hereby incorporated by reference into this application.

### TECHNICAL FIELD

The present invention relates to the manufacturing technology of a semiconductor device, and particularly relates to an effective technology in the application to the manufacturing technology of the semiconductor device which has a step which does Chemical Mechanical Polishing (Chemical Mechanical Polishing: CMP) of the semiconductor wafer.

### BACKGROUND ART

The manufacturing process of the semiconductor device includes various CMP processes. For example, there is a CMP process at the time of forming an embedding insulating film as an element isolation region in a semiconductor wafer by the STI (Shallow Trench Isolation) method, a CMP process at the time of doing flattening of the interlayer insulation film formed on the semiconductor wafer, a CMP process at the time of embedding a conductive material in the through hole formed in the interlayer insulation film, and forming a plug in it, or a CMP process at the time of forming an embedded wiring by the damascene method.

In the Japanese Unexamined Patent Publication No. Hei 9-19863 (Patent Reference 1) or the corresponding U.S. Pat. No. 5,795,215 official report, the technology which does the screw stop of the wafer outer-edge holding ring made from a plastic material to the wafer outer-edge holding ring backing ring made from aluminum in polishing head structure is described.

In Japanese Unexamined Patent Publication No. 2003-124169 (Patent Reference 2), the technology that while the insertion which has a female-screw part is penetrated in one through hole of the through holes formed in each of a holder and a retaining ring, the bolt member which has a male-screw part is penetrated in the through hole of another side, and a holder and a retaining ring are attached by screwing this insertion and the bolt member in the wafer grinding apparatus which stretches a protective sheet inside a retaining ring, pushes and attaches a wafer against a polishing pad via a protective sheet, and polishes it while attaching a retaining ring to the holder of the wafer holding head is described.

In Japanese Unexamined Patent Publication No. 2003-179014 (Patent Reference 3), the technology that while the periphery portion of a protective sheet is pinched with a retaining ring and a holder, the tension adjustment means of the protective sheet is formed in the inner circumference side of this sandwiching part, and the tension of the stretched protective sheet constitutes variable by the tension adjustment means in the wafer grinding apparatus which stretches a protective sheet inside a retaining ring, pushes and attaches a wafer against a polishing pad via a protective sheet, and polishes it while attaching a retaining ring to the holder of a wafer holding head is described.

In Japanese Unexamined Patent Publication No. Hei 11-291162 (Patent Reference 4) or the corresponding U.S. Pat. No. 6,277,008 official report, the technology formed so that a retaining ring might consist of a resin part which consists of rigid plastics, such as polyethylene terephthalate, and metal parts, such as stainless steel, and the resin part might cover the whole maintenance member surface is described.

In Japanese Unexamined Patent Publication No. 2003-179015 (Patent Reference 5) or its corresponding U.S. Pat. No. 6,251,215 official report, the technology set as the structure that the carrier head for chemical mechanical grinding apparatuses has a retaining ring which has a portion of the flexible lower part, and a rigid upside portion, and whose retaining ring of this contacts a polishing pad between polishes, and has the portion of the lower part which has a bottom front surface currently made from the first material, and the upside portion currently made from the second material that is rigidity from the first material is described.

In Japanese Unexamined Patent Publication No. 2001-71255 (Patent Reference 6) or the corresponding European patent disclosure No. 1080841 official report, the technology, in a polishing head, a retaining ring is fixed to a carrier, an elastic membrane is located in the under surface of a carrier, and the edge part of the elastic membrane is pinched and fixed between the retaining ring and the carrier, and the fluid supply way is formed for supplying variable pressure fluid between the elastic membrane and the carrier in the carrier is described.

In Japanese Unexamined Patent Publication No. 2004-6653 (Patent Reference 7) or its corresponding U.S. Pat. No. 6,773,338 official report, the technology in which compression bonding fixation of the retaining ring for preventing that the wafer fixed to the porous film breaks away outside was done with the clamp ring clamped with the lower plate with the bolt at the lower plate marginal part of the polishing head is described.

In Japanese Unexamined Patent Publication No. Hei 11-333711 (Patent Reference 8), the technology regarding the polishing head provided with the housing which has structure with a stage inside, the retaining ring fixed around housing, the elastic body film held with the retaining ring, and the mechanism that air is introduced into the sealing space formed with housing, a retaining ring, and an elastic body film, or air is sucked from sealing space is described.

In Japanese Unexamined Patent Publication No. 2003-39306 (Patent Reference 9), the technology that the wafer carrier of a wafer grinding apparatus consists of a carrier body, a retaining ring which supports the wafer under polish to a hoop direction, and a thin film member that transmits thrust to a wafer, and which is formed so that the first press means using air pressure that pushes and presses a thin film member might be formed and the second press means that pushes and presses a retaining ring below with air pressure might be formed apart from the first press means in a carrier body is described.

[Patent Reference 1] Japanese Unexamined Patent Publication No. Hei 9-19863

[Patent Reference 2] Japanese Unexamined Patent Publication No. 2003-124169

[Patent Reference 3] Japanese Unexamined Patent Publication No. 2003-179014

[Patent Reference 4] Japanese Unexamined Patent Publication No. Hei 11-291162

[Patent Reference 5] Japanese Unexamined Patent Publication No. 2003-179015

[Patent Reference 6] Japanese Unexamined Patent Publication No. 2001-71255

[Patent Reference 7] Japanese Unexamined Patent Publication No. 2004-6653

[Patent Reference 8] Japanese Unexamined Patent Publication No. Hei 11-333711

[Patent Reference 9] Japanese Unexamined Patent Publication No. 2003-39306

### DISCLOSURE OF THE INVENTION

In a CMP process, it is pushing and attaching the semiconductor wafer held in the wafer holding part, supplying polishing liquid to the polishing pad stuck on the rotating platen of a CMP device (turn table), and a semiconductor wafer is polished.

The uniformity of the polishing quantity within a semiconductor wafer surface of a CMP device depends on the surface form of the retaining ring attached to the wafer holding part greatly. Since the front surface of a retaining ring is also polished with a semiconductor wafer, the surface state of a retaining ring influences the polish state of a semiconductor wafer (especially wafer edge part). The grinding rate of the wafer edge part of a semiconductor wafer may change with the abrasion states of a retaining ring, when abrasion of a retaining ring progresses, the polishing quantity uniformity within a plane of a semiconductor wafer may stop stabilizing, and the quality of the semiconductor device manufactured may be changed. For this reason, flatness control of the front surface of a retaining ring and periodical exchange of a retaining ring are needed. Since retaining rings are expensive consumable goods, cost reduction of a retaining ring and improvement in a replacement life are aimed at, and to reduce the manufacturing cost of a semiconductor device is desired. The operating ratio of a CMP device is reduced and the manufacturing cost of a semiconductor device may be increased when complicated work is required for exchange of a retaining ring. For this reason, a retaining ring exchangeable with a simple technique is desired.

When retaining rings are exchanged and the fixation condition of the retaining ring to a wafer holding part is changed, after exchanging for a new retaining ring, before starting the CMP treatment of a product wafer (semiconductor wafer for manufacturing a semiconductor device), by setting the conditions of a retaining ring, etc., it is necessary to adjust or confirm the grinding rate of the edge part of a semiconductor wafer. This will reduce the operating ratio of a CMP device and will increase the manufacturing cost of a semiconductor device.

One purpose of one invention disclosed by the present application is to offer the technology in which the manufacturing cost of a semiconductor device can be reduced.

Of the inventions disclosed in the present application, typical ones will next be summarized briefly.

As for one invention disclosed by the present application, a semiconductor wafer is held in a wafer holding part with the retaining ring which did the screw stop to the wafer holding part from the lower part and which includes a resin material, and Chemical Mechanical Polishing of the semiconductor wafer is done where almost the whole surface of the back surface of a wafer (mechanical pressure is generally applied in many cases as for a periphery) is pressurized via membrane (or flexible thin film) by static gas pressure (or compressible fluid pressure) or semi-static gas pressure.

One invention disclosed by the present application does Chemical Mechanical Polishing of the semiconductor wafer, where a semiconductor wafer is held in a wafer holding part with the retaining ring which did the screw stop to the wafer holding part from the lower part and which includes a resin material.

As for one invention disclosed by the present application, Chemical Mechanical Polishing of the semiconductor wafer is done where a semiconductor wafer is held in a wafer holding part with the retaining ring which did the screw stop to the wafer holding part from the lower part and which includes a resin material, and a screw hole for doing the screw stop of the retaining ring is formed in the groove formed in the under surface of the retaining ring.

As for one invention disclosed by the present application, Chemical Mechanical Polishing of the semiconductor wafer is done where a semiconductor wafer is held in a wafer holding part with the retaining ring which did the screw stop to the wafer holding part from the lower part and which includes a resin material, a diaphragm is fixed to a wafer holding part by a diaphragm holddown member, and the screw stop of the retaining ring is done to this diaphragm holddown member from the lower part.

As for one invention disclosed by the present application, Chemical Mechanical Polishing of the semiconductor wafer is done where a semiconductor wafer is held in a wafer holding part with the retaining ring which did the screw stop to the wafer holding part from the lower part and which includes a resin material, an elastic membrane is fixed to a wafer holding part by an annular metal member, and the screw stop of the retaining ring is done to this metal member from the lower part.

Advantages achieved by some of the most typical aspects of the invention disclosed in the present application will be briefly described below.

The manufacturing cost of a semiconductor device can be reduced.

### BRIEF DESCRIPTION OF THE DRAWINGS

FIG. 1 is a principal part cross-sectional view of a semiconductor wafer showing the manufacturing process of a semiconductor device which is the 1 embodiment of the present invention;

FIG. 2 is a principal part cross-sectional view in the manufacturing process of a semiconductor device following FIG. 1;

FIG. 3 is a principal part cross-sectional view in the manufacturing process of a semiconductor device following FIG. 2;

FIG. 4 is a principal part cross-sectional view in the manufacturing process of a semiconductor device following FIG. 3;

FIG. 5 is a principal part cross-sectional view in the manufacturing process of a semiconductor device following FIG. 4;

FIG. 6 is a principal part cross-sectional view in the manufacturing process of a semiconductor device following FIG. 5;

FIG. 7 is a principal part cross-sectional view in the manufacturing process of a semiconductor device following FIG. 6;

FIG. 8 is a principal part cross-sectional view in the manufacturing process of a semiconductor device following FIG. 7;

FIG. 9 is a principal part cross-sectional view in the manufacturing process of a semiconductor device following FIG. 8;

FIG. 10 is an explanatory diagram showing the processing sequence of a CMP process;

FIGS. 11 and 12 are explanatory diagrams showing the rough structure of a CMP device;

FIG. 13 is an explanatory diagram showing a state that CMP treatment of the semiconductor wafer is done by one platen in a plurality of platens which form a CMP device;

FIG. 14 is a principal part cross-sectional view of a polishing head;

FIG. 15 is a principal part cross-sectional view of the retaining ring neighboring region of a polishing head;

FIG. 16 is a plan view of a diaphragm stop ring;

FIG. 17 is a plan view showing the state where the retaining ring was attached to the diaphragm stop ring;

FIGS. 18 to 20 are principal part cross-sectional views showing the state where the retaining ring was attached to the diaphragm stop ring;

FIG. 21 is a principal part cross-sectional view showing the polishing head of the first comparative example;

FIG. 22 is a principal part cross-sectional view showing the polishing head of the second comparative example;

FIG. 23 is an explanatory diagram showing the abrasion model of a retaining ring;

FIG. 24 is a cross-sectional view showing notionally the state where polishing liquid invaded between the diaphragm stop ring and the retaining ring;

FIG. 25 is a plan view showing the under surface of the diaphragm stop ring when removing a retaining ring, after performing CMP treatment;

FIG. 26 is a plan view of the retaining ring of other embodiments of the present invention; and

FIG. 27 is a cross-sectional view of the retaining ring of other embodiments of the present invention.

### BEST MODE FOR CARRYING OUT THE INVENTION

Prior to detailed description of the inventions according to this application, the meanings of the terms used herein will next be described.

1. When saying a substance name, such as silicon, except for the case where especially that is described, not the thing that shows only the displayed substance but the thing which uses the shown substances (an element, an atomic group, a molecule, a macromolecule, a copolymer, a compound, etc.) as main components and a composition component shall be included.

That is, even if it calls it a silicon region etc., except for the time of specifying especially that that is not right, a pure silicon region, the region which uses as main components the silicon which doped the impurity, the mixed crystal region that uses silicon as main constituent elements like GeSi, etc. shall be included. Except for the time of specifying that that is not right in particular, “M” when calling it MIS shall not be limited to a pure metal, and shall include the member which shows character similar to metal of a polysilicon (amorphous state is included) electrode, a silicide layer, and others. Except for the time of specifying that that is not right in particular, “I” when calling it MIS shall not be limited to oxide films, such as a silicon oxide film, but shall include usual dielectrics, a high dielectric, a ferro electric substance film, etc. such as nitride film, oxynitride film, alumina film, etc.

2. The term “wafer” means an insulation, a half-insulation, or a semiconductor substrate and those complex substrates such as silicon and other semiconductor single crystal substrates (generally almost disk type, semiconductor wafer and other semiconductor chip or a pellet and its base substance region which are divided into the unit integrated circuit region), an epitaxial substrate, a sapphire substrate, glass substrates, etc. which are used for manufacture of semiconductor integrated circuit.

3. The term “Chemical Mechanical Polishing (CMP)” means polishing by doing relative displacement to a plane direction generally, supplying slurry, where a polished surface is contacted to the polishing pad which includes the relatively soft cloth's sheet material etc. In this embodiment, in addition, CML (Chemical Mechanical Lapping) which polishes by doing relative displacement of the polished surface to a hard grinding wheel surface, the other things which use fixed abrasive, abrasive particle free CMP which does not use an abrasive particle, etc. shall be included.

4. Although the term “polishing liquid (slurry)” generally means the soil suspension which mixed polished abrasive to chemical etching chemicals, that with which polished abrasive is not mixed shall also be included.

5. Generally, the term “embedded wiring” or “embedded metal wiring” means, like single damascene or dual damascene, the wiring patterned by the wiring formation technology of removing the unnecessary electric conduction film on an insulating film after embedding an electric conduction film to the inside of wiring openings, such as a groove formed in the insulating film and a hole. Generally, the term “single damascene” means the embedded wiring process divided and embedded in two steps of a plug metal and the metal for a wiring. The term “dual damascene” means similarly the embedded wiring process which generally embeds a plug metal and the metal for a wiring at once. Generally, a copper embedded wiring is used with multilayer structure in many cases.

6. The term “semiconductor device” in present application, not only means what is made on single crystal silicon substrate especially, but except for the case where it is specified especially that that is not right, things made on other substrates, such as an epitaxial substrate, an SOI (Silicon On Insulator) substrate, and a substrate for TFT (Thin Film Transistor) liquid crystal manufacture, shall be included.

7. The term “semiconductor integrated circuit chip” or “semiconductor chip” (only henceforth a chip) means what divided into the unit circuit group the wafer to which the wafer step (a wafer process or preceding process) completed.

8. The insulating film which has a dielectric constant lower than the dielectric constant of the silicon oxide film (for example, TEOS (Tetraethoxysilane) oxide film) included in a passivation film can be exemplified as a low dielectric constant insulating film (Low-K insulating film). Generally, below the relative dielectric constant ε about 4.1˜4.2 of a TEOS oxide film is called low dielectric constant insulating film.

In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated.

In the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number.

In the below-described embodiments, it is needless to say that the constituting elements (including element steps) are not always essential unless otherwise specifically indicated or principally apparent that they are essential.

In the below-described embodiments, when a reference is made to the shape or positional relationship of the constituting elements, that substantially analogous or similar to it is also embraced unless otherwise specifically indicated or principally apparent that it is not. This also applies to the above-described value and range.

In all the drawings for describing the embodiments, members of a like function will be identified by like reference numerals and overlapping descriptions will be omitted.

In the drawings used in the below-described embodiments, even a plan view is sometimes partially hatched for facilitating understanding of it. Hatching may be omitted even if it is a cross-sectional view.

Hereafter, embodiments of the invention are explained in detail based on drawings.

### EMBODIMENT 1

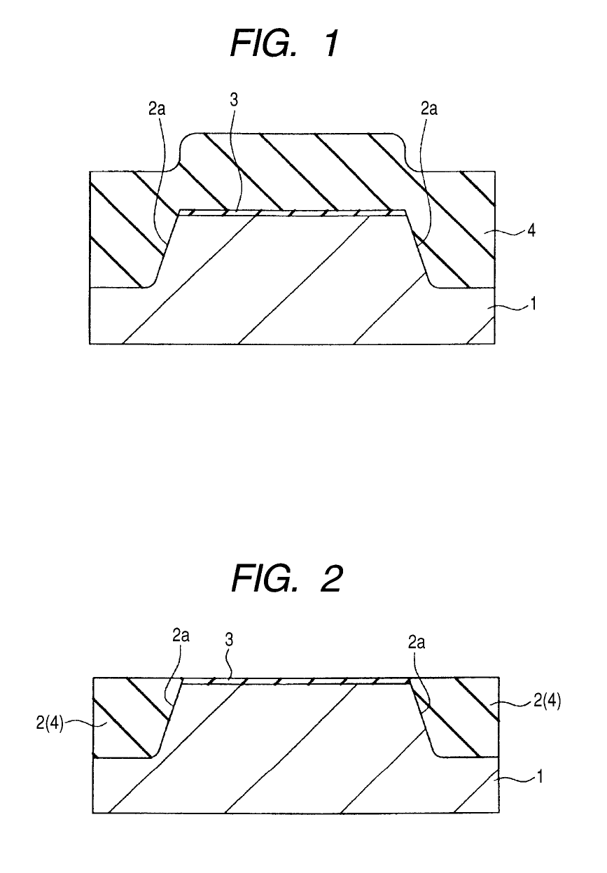

FIG. 1-FIG. 9 are the principal part cross-sectional views in the semiconductor device which is the 1 embodiment of the present invention, for example, the manufacturing process of MISFET (Metal Insulator Semiconductor Field Effect Transistor).

First, semiconductor wafer (a wafer, semiconductor substrate) 1 which includes p type single crystal silicon which has the resistivity about 1˜10 Ω cm, for example is prepared. And element isolation region 2 which includes an insulator is formed in the main surface at the side of semiconductor element formation of semiconductor wafer 1 using the STI (Shallow Trench Isolation or SGI:Shallow Groove Isolation) method etc. Element isolation region 2 can be made like next, for example, and can be formed.

That is, as shown in FIG. 1, insulating film 3 which includes a silicon nitride etc., for example is formed in the main surface of semiconductor wafer 1, and insulating film 3 is patterned after it using the photolithography method, the dry etching method, etc. And semiconductor substrate 1 is etched to the predetermined depth, using patterned insulating film 3 as an etching mask, and element isolation groove 2a is formed in the main surface of semiconductor wafer 1. After oxidizing a bottom, a side wall, etc. of element isolation groove 2a by a thermal oxidation method etc. according to need, insulating film 4 which includes silicon oxide etc. is formed on semiconductor wafer 1 so that element isolation groove 2a may be filled.

Next, as shown in FIG. 2, CMP (Chemical Mechanical Polishing, chemical mechanical polish) processing is performed, insulating film 4 is polished, it leaves insulating film 4 in element isolation groove 2a, and the unnecessary portion of the other insulating film 4 is removed. Hereby, element isolation region 2 which includes insulating film 4 which fills element isolation groove 2a can be formed. Then, insulating film 3 which remains is removed. Element isolation region 2 functions as separating between each element (a semiconductor element, for example, MISFET) formed in semiconductor wafer 1. This loses the electric interference between the formed elements, and it becomes possible to control each element independently.

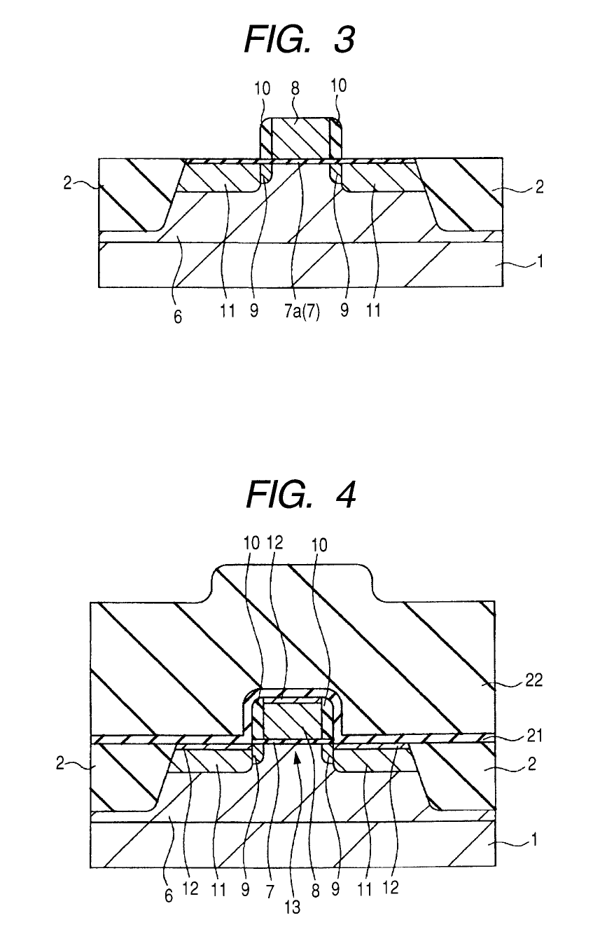

Next, as shown in FIG. 3, p type well 6 is formed in the region which forms n channel type MISFET of semiconductor wafer 1. P type well 6 can be formed for example, by doing the ion implantation of the p type impurities, such as boron (B), etc.

Next, insulating film 7a for gate insulating film formation is formed in the front surface of p type well 6. Insulating film 7a includes a thin silicon oxide film etc., for example, and can be formed, for example by a thermal oxidation method etc.

Next, gate electrode 8 is formed on insulating film 7a of p type well 6. For example, a polycrystalline silicon film is formed on the main surface of semiconductor wafer 1, the ion implantation of the phosphorus (P) etc. is done to the polycrystalline silicon film, and it is set as the n-type semiconductor film of low resistance. By patterning the polycrystalline silicon film by dry etching, gate electrode 8 which includes a patterned polycrystalline silicon film can be formed. Insulating film 7a under gate electrode 8 turns into gate insulating film 7 of MISFET.

Next, n⁻type semiconductor region (pair) 9 is formed by doing the ion implantation of the impurity of n types, such as phosphorus (P) or arsenic (As), to the region of the both sides of gate electrode 8 of p type well 6.

Next, the side wall spacer or sidewall 10 which includes silicon oxide etc., for example is formed on the side wall of gate electrode 8. Sidewall 10 can be formed by for example, depositing a silicon oxide film on semiconductor wafer 1, and doing anisotropic etching of this silicon oxide film.

After formation of sidewall 10, n⁺ type semiconductor region (pair) 11 (a source, a drain) is formed by for example, doing the ion implantation of the impurity of n types, such as phosphorus (P) or arsenic (As), to the region of the both sides of gate electrode 8 and sidewall 10 of p type well 6. Annealing treatment for activation of the introduced impurity (heat treatment) can also be performed after ion implantation. n⁺ type semiconductor region 11 has impurity concentration higher than n⁻type semiconductor region 9. Hereby, the semiconductor region (impurity diffused layer) of n type which functions as the source or drain of n channel type MISFET is formed by n⁺ type semiconductor region 11 and n⁻ type semiconductor region 9.

Next, by exposing the front surface of gate electrode 8 and n⁺ type semiconductor region 11, and for example, by depositing and heat-treating a cobalt (Co) film, as shown in FIG. 4, metal silicide film (for example, cobalt silicide (CoSi₂) film) 12 is formed in the front surface of gate electrode 8 and n⁺ type semiconductor region 11, respectively. Hereby, diffusion resistance, such as n⁺ type semiconductor region 11, and contact resistance can be reduced. Then, an unreacted cobalt film is removed.

Thus, n channel type MISFET(Metal Insulator Semiconductor Field Effect Transistor) 13 is formed in p type well 6. The conductivity type of n type and p type can be made reverse, and p channel type MISFET can also be formed.

Next, on semiconductor wafer 1, relatively thin insulating film (etching stopper film) 21 which includes a silicon nitride film etc., and relatively thick insulating film (interlayer insulation film) 22 which includes a silicon oxide film etc. are deposited one by one, for example using a CVD method etc. so that gate electrode 8 may be covered. Insulating film 21 at the side of a lower layer can function as an etching stopper film at the time of the contact hole 23 formation mentioned later. Insulating film 21 at the side of a lower layer is also omissible when unnecessary.

Next, as shown in FIG. 5, CMP treatment is performed, insulating film 22 is polished, and flattening of the front surface of insulating film 22 is done.

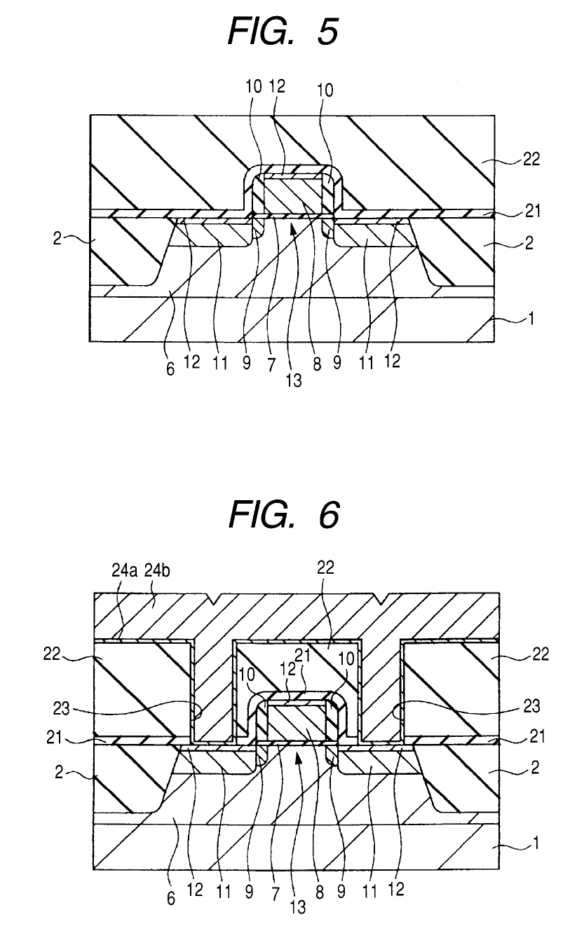

Next, as shown in FIG. 6, by doing dry etching of insulating film 22 and the insulating film 21 one by one using the photoresist pattern (not shown) formed on insulating film 22 using the photolithography method as an etching mask, contact hole (opening) 23 is formed in the upper part of n⁺ type semiconductor region (a source, a drain) 11 etc. At the bottom of contact hole 23, a part of main surface of semiconductor wafer 1, for example, a part of (silicide film 12 on the front surface of) n⁺ type semiconductor region 11, and a part of (silicide films 12 on the front surface of) gate electrode 8 are exposed.

Next, barrier film (for example, titanium nitride film) 24a is formed on insulating film 22 comprising the inside of contact hole 23. And tungsten film 24b is formed so that the inside of contact hole 23 may be filled with a CVD method etc. on barrier film 24a.

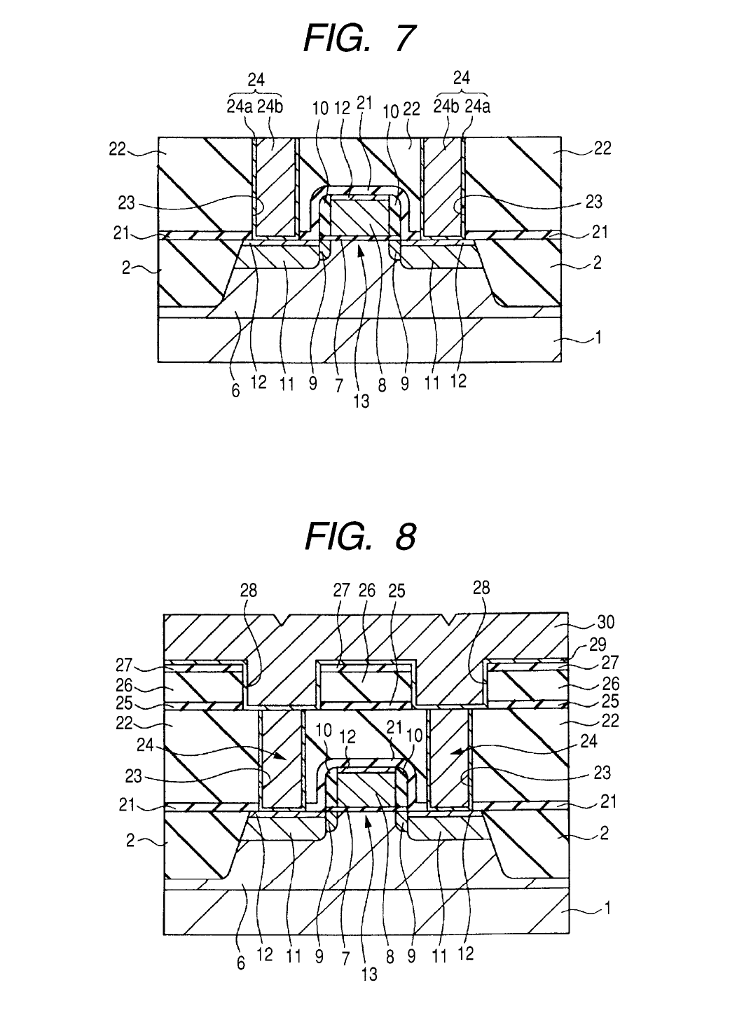

Next, as shown in FIG. 7, CMP treatment is performed, and tungsten film 24b and barrier film 24a are polished until the upper surface of insulating film 22 is exposed. By removing unnecessary tungsten film 24b and unnecessary barrier film 24a on insulating film 22, and leaving tungsten film 24b and barrier film 24a in contact hole 23 by this CMP treatment, plug 24 embedded in contact hole 23 can be formed.

Next, as shown in FIG. 8, insulating film (etching stopper film) 25, insulating film (interlayer insulation film) 26, and insulating film 27 are formed in order on insulating film 22 where plug 24 was embedded. Insulating film 25 includes a silicon nitride film or a silicon carbide film, for example, and can function as an etching stopper film at the time of etching insulating film (interlayer insulation film) 26. Insulating film 26 as an interlayer insulation film can be formed with low dielectric constant material (the so-called Low-K insulating film, Low-K material) etc. Insulating film 27 can be formed, for example with a silicon oxide film etc., for example, can have functions at the time of CMP treatment, such as reservation of mechanical strength, a surface protection, moisture resistance reservation, etc. of insulating film 26.

Next, using the photolithography method and the dry etching method, insulating films 25, 26, and 27 are removed selectively, and opening (a wiring opening, a wiring gutter) 28 is formed. At this time, the upper surface of plug 24 is exposed at the bottom of opening 28.

Next, after forming relatively thin electrically conductive barrier film (for example, titanium nitride film) 29 on the whole surface on the main surface of semiconductor wafer 1 (namely, on insulating film 27 of opening 28 comprising bottom and side wall upper part), relatively thick main conductor film 30 which includes copper is formed so that the inside of opening 28 may be filled on electrically conductive barrier film 29.

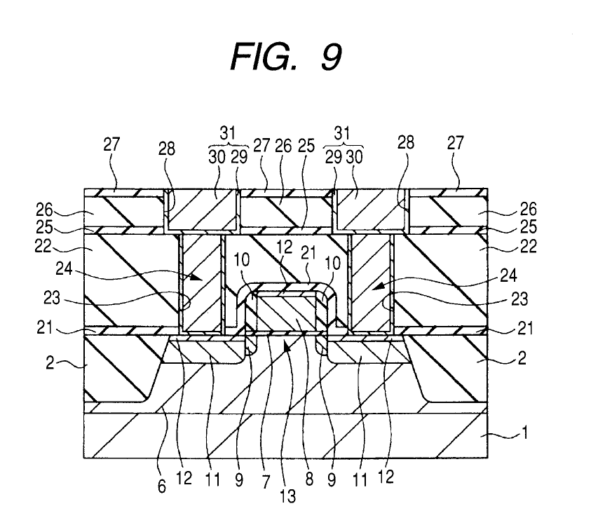

Next, as shown in FIG. 9, CMP treatment is performed, and main conductor film 30 and electrically conductive barrier film 29 are polished until the upper surface of insulating film 27 is exposed. By removing unnecessary electrically conductive barrier film 29 and unnecessary main conductor film 30 on insulating film 27, and leaving electrically conductive barrier film 29 and main conductor film 30 in opening 28 by this CMP treatment, wiring (first layer wiring, embedded copper wiring) 31 is formed in opening 28. Formed wiring 30 is electrically connected with n⁺ type semiconductor region 11 for a source or a drain, gate electrode 8, etc. of n channel type MISFET13 via plug 24.

Then, although an interlayer insulation film, the upper wiring layer, etc. are further formed on insulating film 27 comprising upper surface upper part of wiring 31, illustration and its explanation are omitted here.

Thus, the manufacturing process of the semiconductor device includes various CMP processes. For example, there is a CMP process at the time of forming element isolation region 2, a CMP process at the time of doing flattening of the interlayer insulation film (for example, insulating film 22) formed on the semiconductor wafer, a CMP process at the time of embedding a conductive material in the through hole (for example, contact hole 23) formed in the interlayer insulation film, and forming a plug (for example, plug 24) in it or a CMP process at the time of forming an embedded wiring (for example, wiring 31) by the damascene method.

Next, the CMP (Chemical Mechanical Polishing) step performed by this embodiment is explained.

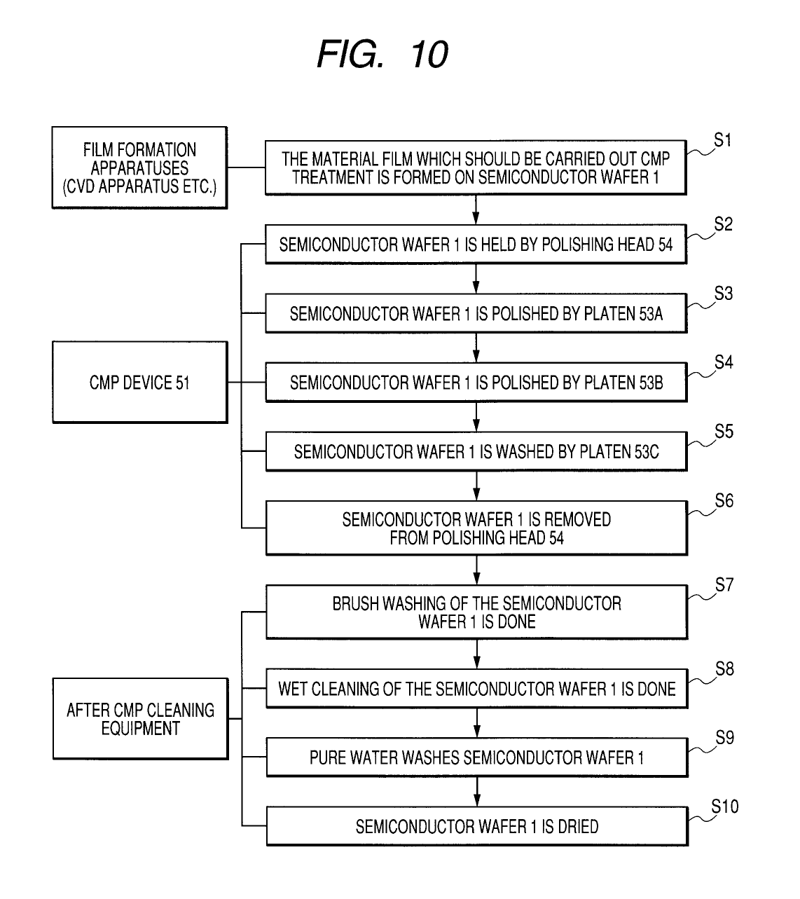

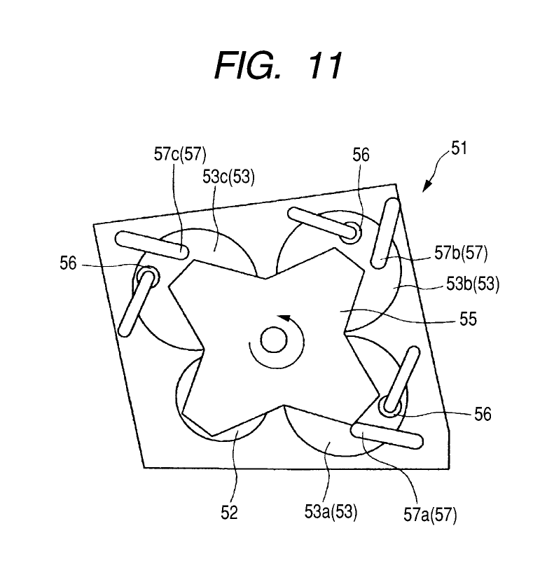

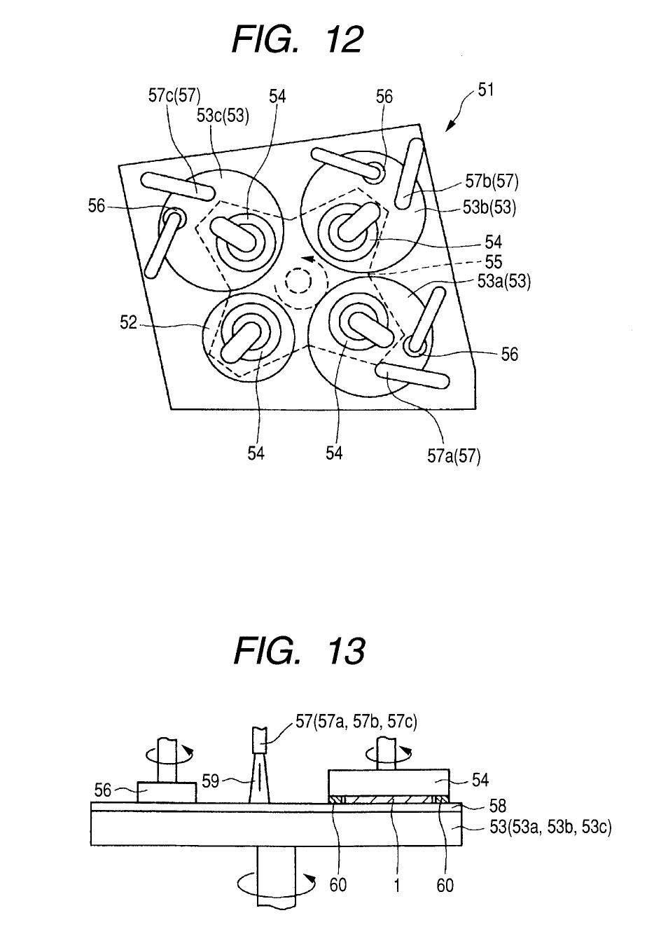

FIG. 10 is an explanatory diagram showing the processing sequence (flow) of the CMP process. FIG. 11 and FIG. 12 are the explanatory diagrams (plan view) showing the rough structure of CMP device 51 used for the CMP process performed by this embodiment. FIG. 13 is an explanatory diagram (side view) showing a state that CMP treatment of the semiconductor wafer 1 is done by one platen 53 in a plurality of platens 53 which form CMP device 51. As for FIG. 12, the state where multi head holding part 55 was seen through in CMP device 51 of FIG. 11 is shown.

As shown in FIG. 11 and FIG. 12, CMP device 51 used for the CMP process performed by this embodiment is a CMP device of a multi-platen/multi head system. The throughput of CMP treatment can be improved by doing the sheet process of the semiconductor wafer using CMP device 51 of a multi-platen/multi head system.

CMP device 51 shown in FIG. 11, FIG. 12, and FIG. 13 has load cup 52 for loading and unloading of a semiconductor wafer, a plurality of pivotable platens (turn table) 53, for example, three platens (turn table) 53a, 53b, and 53c, and a plurality of polishing heads 54 which can hold a semiconductor wafer (a wafer holding part, a wafer holding head, a wafer carrier), for example, four polishing heads 54. These four polishing heads 54 are supported by multi head holding part 55, and each polishing head 54 is formed pivotable, where a semiconductor wafer is held. Polishing pad (polishing cloth) 58 is stuck on the upper surface of each platen 53. Three polishing heads 54 on platens 53a, 53b, and 53c of four polishing heads 54 are formed so that a semiconductor wafer may be held and the semiconductor wafer may be pushed and attached against polishing pad 58 of the upper surface of platens 53a, 53b, and 53c. One polishing head 54 on load cup 52 of four polishing heads 54 is formed so that a semiconductor wafer may be received from load cup 52 and a semiconductor wafer may be sent out to load cup 52. As a polishing pad stuck on the upper surface of each platens 53a, 53b, and 53c, the polishing pad which uses, for example foaming polyurethane as the main ingredients can be used.

CMP device 51 further has conditioner (dressing, dressing member) 56 for doing dressing processing (dressing processing of polishing pad 58, processing which corrects or restores the front surface of polishing pad 58 smoothed by abrasion etc. using a diamond wheel (abrasive particle) etc.) of polishing pad 58 of the upper surface of each platens 53a, 53b, and 53c, and nozzle 57 for supplying liquids 59, such as polishing liquid (slurry, drug solution) or water (pure water), to polishing pad 58 of the upper surface of each platens 53a, 53b, and 53c. Platens 53a, 53b, and 53c, polishing head 54, and conditioner 56 are formed by the motor etc. pivotable, respectively. Polishing head 54 can do a chuck of a semiconductor wafer, and can hold it.

Among nozzles 57, nozzle 57a supplies polishing liquid (slurry, drug solution) to polishing pad 58 of the upper surface of platen 53a, nozzle 57b supplies polishing liquid (slurry, drug solution) to polishing pad 58 of the upper surface of platen 53b, and nozzle 57c supplies water (pure water) to polishing pad 58 of the upper surface of platen 53c. Therefore, platen 53a and platen 53b are the polish platens for mainly polishing using the slurry for polish among platens 53a, 53b, and 53c. Platen 53c is the buff platen for mainly washing not using the slurry for polish but using water (pure water). In the front surface (plane which contacts polishing pad 58 in dressing processing) of conditioner 56, the diamond wheel (abrasive particle) etc. is embedded, for example.

Next, the outline of operation of CMP treatment using CMP device 51 is explained.

As shown in FIG. 10, the material film (for example, the above-mentioned insulating film 4, insulating film 22, and barrier film 24a and tungsten film 24b, or electrically conductive barrier film 29 and main conductor film 30, etc.) which should perform CMP treatment are formed on the main surface of semiconductor wafer 1 using a film formation apparatus (for example, CVD apparatus etc.) (Step S1). Then, it is sent to load cup 52 of CMP device 51 through the conveying equipment which is not illustrated, and is held at polishing head 54 on load cup 52 (Step S2). As for semiconductor wafer 1 held (supported) at polishing head 54 , by the rotation of multi head holding part 55, while moving on three platens 53a, 53b, and 53c one by one, polish (CMP treatment) is advanced.

That is, when multi head holding part 55 rotates, polishing head 54 on each platens 53a, 53b, and 53c and load cup 52 moves onto following platen 53 or following load cup 52. On this occasion, polishing head 54 which held semiconductor wafer 1 with load cup 52 moves onto platen 53a, when multi head holding part 55 rotates. And as shown in FIG. 13, the front surface (main surface at the side in which the material film which should be carried out CMP treatment was formed) of semiconductor wafer 1 which is held (supported) at polishing head 54 and rotates contacts to polishing pad 58 of the upper surface of rotating platen 53a. Semiconductor wafer 1 is pushed against a polishing pad by predetermined pressure. On this occasion, polishing liquid is supplied to polishing pad 58 of the upper surface of platen 53a as liquid 59 from nozzle 57a. Rubbing of the front surface of semiconductor wafer 1 and the polishing pad of the upper surface of platen 53a is done by those rotations, supplying polishing liquid on polishing pad 58. Chemical Mechanical Polishing (CMP) of the front surface of semiconductor wafer 1 is done (Step S3). Hereby, CMP (Chemical Mechanical Polishing) processing of the material film which was formed in the front surface of semiconductor wafer 1 and which should be carried out CMP treatment is done. Conditioner 56 is forced on polishing pad 58 of the upper surface of platen 53a by predetermined pressure, and the polish conditions of polishing pad 58 can be maintained by doing dressing processing of the front surface of polishing pad 58. The screw stop of the retaining ring 60 which includes a resin material is done to polishing head 54 from the lower part so that it may mention later. This retaining ring 60 prevents that semiconductor wafer 1 shifts from polishing head 54 in polish. That is, where (the outer edge of) semiconductor wafer 1 is held (supported) to polishing head 54 with retaining ring 60, Chemical Mechanical Polishing of the semiconductor wafer 1 can be done. Although retaining ring 60 has the form of annular shape (ring shape) which surrounds semiconductor wafer 1, the section of retaining ring 60 is shown by FIG. 13.

After polish of predetermined thickness is performed by platen 53a, when multi head holding part 55 rotates, polishing head 54 on each platens 53a, 53b, and 53c and load cup 52 moves onto following platen 53 or following load cup 52. On this occasion, polishing head 54 on platen 53a moves onto platen 53b, when multi head holding part 55 rotates. And as shown in FIG. 13, the front surface of semiconductor wafer 1 which is held (supported) at polishing head 54 and rotates contacts polishing pad 58 of the upper surface of rotating platen 53b, and semiconductor wafer 1 is pushed against it by predetermined pressure at polishing pad 58. On this occasion, polishing liquid is supplied to polishing pad 58 of the upper surface of platen 53b as liquid 59 from nozzle 57b. Rubbing of the front surface of semiconductor wafer 1 and the polishing pad 58 of the upper surface of platen 53b is done by those rotations, supplying polishing liquid on polishing pad 58. Chemical Mechanical Polishing (CMP) of the front surface of semiconductor wafer 1 is done (Step S4). Hereby, CMP (Chemical Mechanical Polishing) processing of the material film which was formed in the front surface of semiconductor wafer 1 and which should be carried out CMP treatment is done further. Conditioner 56 is forced on polishing pad 58 of the upper surface of platen 53b by predetermined pressure, and the polish conditions of a polishing pad can be maintained by doing dressing processing of the front surface of polishing pad 58. Retaining ring 60 prevents that semiconductor wafer 1 shifts from polishing head 54 in polish.

After polish of predetermined thickness is performed by platen 53b, when multi head holding part 55 rotates, polishing head 54 on each platens 53a, 53b, and 53c and load cup 52 moves onto following platen 53 or following load cup 52. On this occasion, polishing head 54 on platen 53b moves onto platen 53c, when multi head holding part 55 rotates. And as shown in FIG. 13, the front surface of semiconductor wafer 1 which is held (supported) at polishing head 54 and rotates contacts to polishing pad 58 of the upper surface of rotating platen 53c, and semiconductor wafer 1 is pushed against polishing pad 58 by predetermined pressure. On this occasion, pure water (rinsing solution) is supplied to polishing pad 58 of the upper surface of platen 53c as liquid 59 from nozzle 57c. Rubbing of the front surface of semiconductor wafer 1 and the polishing pad 58 of the upper surface of platen 53c is done by those rotations, supplying pure water on polishing pad 58, and the front surface of semiconductor wafer 1 is washed (washed in cold water) (Step S5). Conditioner 56 is forced on polishing pad 58 of the upper surface of platen 53c by predetermined pressure, and dressing processing of the front surface of polishing pad 58 is done. Retaining ring 60 prevents that semiconductor wafer 1 shifts from polishing head 54.

After a cleaning treatment (washing in cold water) is performed by platen 53c, when multi head holding part 55 rotates, polishing head 54 on each platens 53a, 53b, and 53c and load cup 52 moves onto following platen 53 or following load cup 52. On this occasion, polishing head 54 on platen 53c moves onto load cup upper part 52, and is removed from polishing head 54 with load cup 52 (Step S6). Removed semiconductor wafer 1 is sent to cleaning equipment. In cleaning equipment (cleaning process of semiconductor wafer 1 after a CMP process), brush washing of the front surface and back surface of semiconductor wafer 1 is done first (Step S7). The wet cleaning treatment of the semiconductor wafer 1 is done using, for example APM (Ammonia-Hydrogen Peroxide Mixture) liquid, DHF (Diluted Hydrofluoric acid) liquid or HPM (Hydrochloric acid-Hydrogen Peroxide Mixture) liquid (Step S8). It is made to dry (spin drying) by rotating semiconductor wafer 1, after pure water washes semiconductor wafer 1 (Step S9), spraying (blowing) nitrogen gas etc. (Step S10). A CMP process, and a subsequent cleaning process after CMP are performed consistently.

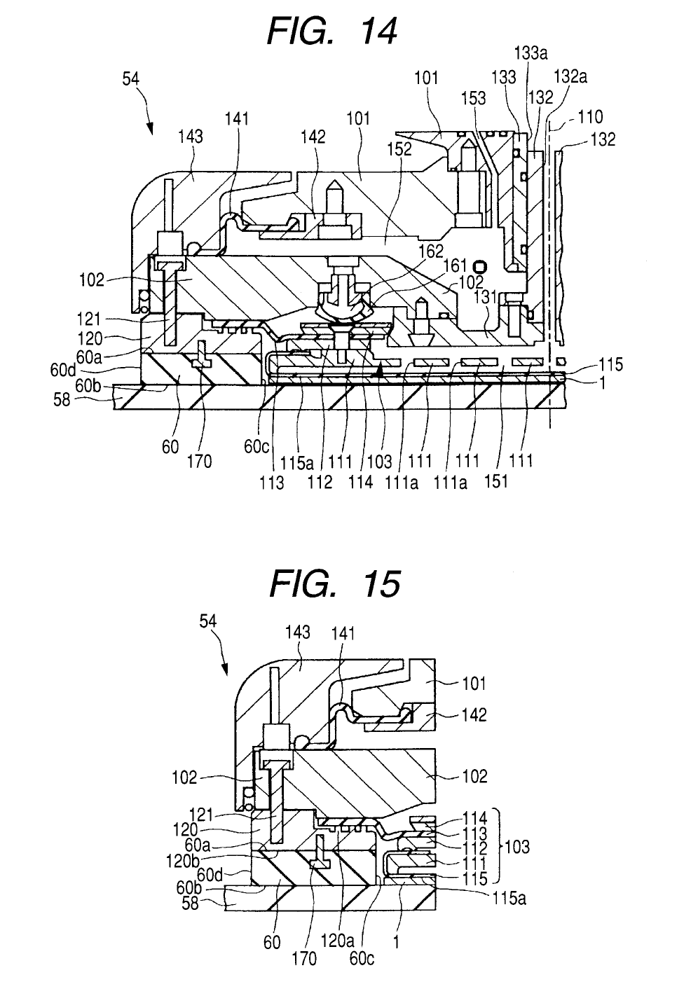

Next, polishing head (a wafer holding part, a wafer holding head, a wafer carrier) 54 of CMP device 51 used for the CMP process performed by this embodiment is explained more to a detail. FIG. 14 is a principal part cross-sectional view of polishing head 54 of CMP device 51, and FIG. 15 is a principal part cross-sectional view of retaining ring 60 neighboring region of polishing head 54. In order to simplify illustration, the cross-sectional view in the left half of polishing head 54 is shown in FIG. 14. What is necessary is just to describe a symmetrical section structure as left-hand side at the right-hand side of revolving shaft 110 shown with an alternate long and two short dashes line, when the cross-sectional view of the whole polishing head 54 is shown.

Polishing head 54 of this embodiment has head body part (housing member) 101, carrier plate (a base member, a sack body) 102, carrier part (wafer backing-strip assembly) 103, and retaining ring 60.

It is formed in about disc-like form, the top center is connected with the rotating shaft (not shown) driven by a motor, and head body part 101 is formed pivotable around revolving shaft 110.

Carrier plate 102 is located under head body part 101, and has about annular form. Carrier plate 102 can be formed with for example, the materials which have rigidity, such as stainless steel.

Carrier part 103 has about disc-like form, and holds one side of semiconductor wafer 1 which should be carried out CMP treatment on the under surface. Carrier part 103 has buttress plate 111 which includes a disc-like member (perforated disk body) which has a plurality of holes lila, first stop ring of annular shape (ring shape) (lower clamp ring) 112 connected to the peripheral part of the upper surface of buttress plate 111, second stop ring of annular shape (ring shape) (upper clamp ring) 114 connected via diaphragm (a diaphragm, a flexor) 113 on first stop ring (clamp) 112, and membrane (a film member, a film-like member) 115 extended and existed under buttress plate 111. The screw stop of buttress plate 111, first stop ring 112, and the second stop ring 114 is done, and they are being fixed.

Diaphragm 113 has a form of annular shape (ring shape). Diaphragm 113 has flexibility, and has elasticity, for example, can form it with elastic body films (elastic membrane), such as rubber. The inner edge of diaphragm 113 is being sandwiched and fixed (clamped) between first stop ring 112 and second stop ring 114. The outer edge of diaphragm 113 is being sandwiched and fixed (clamped) between carrier plate 102, and diaphragm stop ring 120 (a diaphragm holddown member, a flexor stop ring, a clamp ring, a metal member). For this reason, diaphragm 113 can function as sealing the space between the under surface of carrier plate 102, and carrier part 103 (space 151 mentioned later). Diaphragm stop ring 120 has a form of annular shape (ring shape). Diaphragm stop ring 120 is formed with the material whose mechanical strength is higher than retaining ring 60 which includes a resin material, i.e., a metallic material. For example, it is more desirable when forming diaphragm stop ring 120 with materials with high rigidity, such as stainless steel. Diaphragm stop ring 120 is arranged at the peripheral part of the under surface of carrier plate 102. From the upper surface side of carrier plate 102, with screw 121, the screw stop of carrier plate 102 and the diaphragm stop ring 120 is done, and they are being fixed.

Membrane 115 has the circular form of the shape of a thin film. Membrane 115 has flexibility, and has elasticity, for example, can form it with elastic body films (elastic membrane), such as rubber. Membrane 115 is extended and existed under buttress plate 111. The peripheral part of membrane 115 is extended and existed to the upper surface end portion of buttress plate 111 through side wall upper part of buttress plate 111, and is being inserted and fixed (clamped) between buttress plate 111 and first stop ring 1 12.

The screw stop of the carrier plate 102 is done to ring member 131, for example, and it is connected with it. The screw stop of this ring member 131 is done to cylindrical rod 132, for example, and it is connected with it. This rod 132 is inserted in inner hole 133a of cylindrical bush 133 fixed to head body part 101, and can be smoothly moved along this inner hole 133a. Hereby, a motion of the perpendicular direction (up-and-down direction) of carrier plate 102 to head body part 101 can be made possible. A motion of the horizontal direction of carrier plate 102 to head body part 101 can be prevented.

The inner edge of annular (ring shape) diaphragm 141 which includes a flexible elastic body film is being fixed (clamped) to head body part 101 with stop ring (inner clamp ring) 142. The outer edge of diaphragm 141 is being fixed (clamped) to carrier plate 102 with stop ring (outer clamp ring) 143. For this reason, diaphragm 141 can function as sealing the space (space 152 mentioned later) between the under surface of head body part 101, and the upper surface of carrier plate 102.

The pressure of space 151 by which sealing was done between membrane 115, buttress plate 111, first stop ring 112, second stop ring 114, diaphragm 113, (under surface of) carrier plate 102, (under surface of) ring member 131 and (inner wall of) rod 132 is formed controllable. For example, a pump (not shown) etc. is connected to space 151 in fluid via inner hole 133a of bush 133 and inner hole 132a of rod 132, and the pressure of space 151 can be controlled to desired pressure. The force (force or pressure by which membrane 115 pushes semiconductor wafer 1 against polishing pad 58) to the lower part of membrane 115 is controllable by adjusting the pressure of space 151. For example, by introducing pressurization gas into space 151 and heightening the pressure of space 151, membrane 115 can be swollen and the force (pressure) in which membrane 115 pushes semiconductor wafer 1 against polishing pad 58 can be heightened. Membrane 115 can be shrunk with reducing the pressure of space 151, and the force (pressure) in which membrane 115 pushes semiconductor wafer 1 against polishing pad 58 can be reduced. The pressurization conditions on the whole back surface of a wafer from membrane 115 to semiconductor wafer 1 are mainly controllable by adjusting the pressure of space 151 in this way.

It is formed so that the pressure of space 152 by which sealing was done between (under surface of) head body part 101, diaphragm 141, (upper surface of) carrier plate 102, and (outer wall of) rod 132 is controllable. For example, a pump (not shown) etc. is connected to space 152 in fluid via channel (hole) 153, and the pressure of space 152 can be controlled now to desired pressure. Carrier plate 102 can be depressed below and the pressure on which retaining ring 60 pushes polishing pad 58 can be controlled by adjusting the pressure of space 152. For example, by introducing pressurization gas into space 152 and heightening the pressure of space 152, it can be made to be able to act so that carrier plate 102 may be depressed below, and the pressure on which retaining ring 60 pushes polishing pad 58 can be heightened. By reducing the pressure of space 152, it can be made to be able to act so that carrier plate 102 may be moved up, and the pressure on which retaining ring 60 pushes polishing pad 58 can be reduced. It mainly becomes possible by adjusting the pressure of space 152 in this way to control the grinding rate in the wafer edge of semiconductor wafer 1.

Inner tube 161 which includes, for example a flexible elastic body film (elastic membrane) etc. is attached to the under surface of carrier plate 102 at the upper part of second stop ring 114 of carrier part 103. It is formed so that the pressure of space 162 by which sealing was done with inner tube 161 is controllable. For example, the channel connected to the pump (not shown) is connected to space 162 in fluid, and the pressure of space 162 can be controlled now to desired pressure. The grade of expansion of inner tube 161 can be adjusted and the force to the lower part of second stop ring 114 with which inner tube 161 touches, and carrier part 103 can be controlled by adjusting the pressure of space 162. For example, blowing up inner tube 161, the pressure to a lower part is made to act on second stop ring 114 with which inner tube 161 touches by heightening the pressure of space 162. The force (pressure) in which carrier part 103 pushes semiconductor wafer 1 against polishing pad 58 can be heightened. The pressurization conditions of semiconductor wafer 1 near 30 mm from the wafer edge of semiconductor wafer 1 are controllable mainly by adjusting the pressure of space 162 in this way.

Thus, in this embodiment, where the almost whole surface of the back surface of semiconductor wafer 1 (mechanical pressure is generally applied in many cases as for a periphery) is pressurized via membrane 115 (or flexible thin film) by static gas pressure (or compressible fluid pressure) or semi-static gas pressure, Chemical Mechanical Polishing of the semiconductor wafer 1 is done. On this occasion, semiconductor wafer 1 is held to polishing head 54 (wafer holding part) with retaining ring 60 which did the screw stop to polishing head 54 (wafer holding part) from the lower part and which includes a resin material as it may mention later.

As mentioned above, as for diaphragm stop ring 120, as the outer edge section of diaphragm 113 is sandwiched between the upper surface of diaphragm stop ring 120, and the under surface of carrier plate 102, from the upper surface side of carrier plate 102, with screw 121, a screw stop is done to carrier plate 102, and it is being fixed to it. Uneven part 120a is formed in the portion in contact with diaphragm 113 of the upper surface of diaphragm stop ring 120. Diaphragm 113 which includes an elastic body film can be firmly clamped now by this uneven part 120a. Retaining ring 60 is attached to under surface 120b of diaphragm stop ring 120. Retaining ring 60 has annular (ring shape) form, and includes the resin material. So that upper surface 60a of retaining ring 60 may face under surface 120b of diaphragm stop ring 120 and it may contact, from the under surface 60b side of retaining ring 60, with screw 170, the screw stop of the retaining ring 60 is done to diaphragm stop ring 120, and it is being fixed (clamped) to it. 2 gage pins (it corresponds to gage pin 182 mentioned later) are formed as a position gap preventive measure of diaphragm stop ring 120 and retaining ring 60. Diaphragm stop ring 120 and retaining ring 60 have the shape of a ring shape of a concentric circle. Under surface 120b of diaphragm stop ring 120, and upper surface 60a of retaining ring 60 which contacts there have the same form. So, upper surface 60a of retaining ring 60 is certainly fixable to under surface 120b of diaphragm stop ring 120. As mentioned above, by sending fluid (for example gas) into space 152, and heightening the pressure of space 152, carrier plate 102 can be depressed below and retaining ring 60 fixed to carrier plate 102 via diaphragm stop ring 120 can be pushed downward so that it adds load to polishing pad 58. Internal side surface (side surface at the side of an inner circumference) 60c of retaining ring 60 and front surface 115a of membrane 115 form the recess (a hollow part, a recess) which accommodates semiconductor wafer 1. Retaining ring 60 can prevent that semiconductor wafer 1 separates from this recess. That is, where semiconductor wafer 1 is held (supported) to polishing head 54 with retaining ring 60, Chemical Mechanical Polishing of the semiconductor wafer 1 can be done.

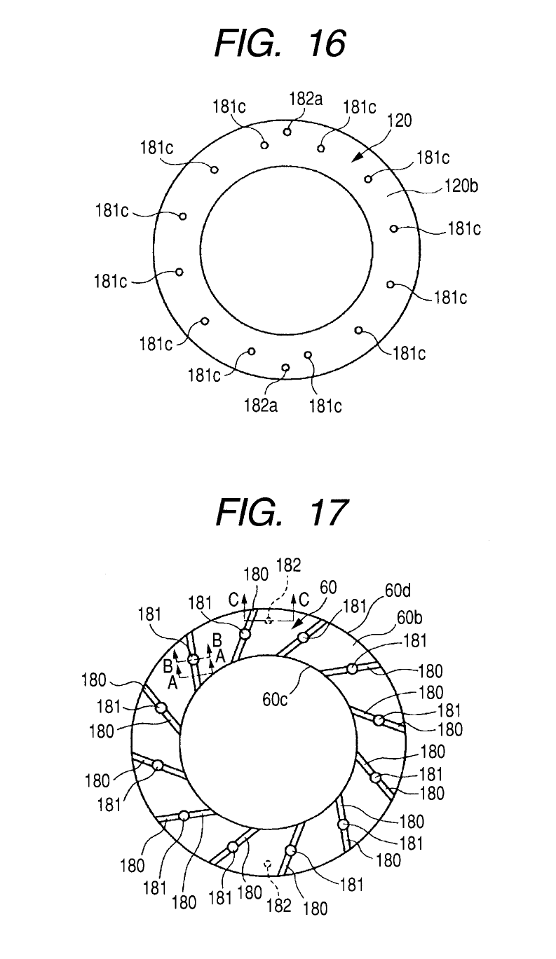

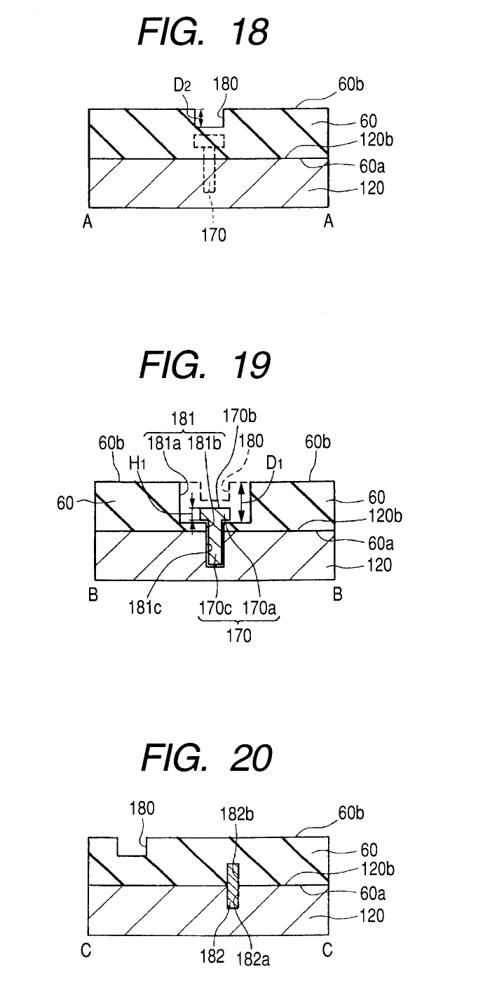

FIG. 16 is a plan view (bottom view) of diaphragm stop ring 120 used by this embodiment. FIG. 17 is a plan view (bottom view) showing the state where retaining ring 60 was attached (the screw stop was done) to diaphragm stop ring 120, and FIG. 18, FIG. 19, and FIG. 20 are the principal part cross-sectional views. The section of the A-A line of FIG. 17 corresponds to FIG. 18, the section of the B-B line of FIG. 17 corresponds to FIG. 19, and the section of the C-C line of FIG. 17 corresponds to FIG. 20. FIG. 16 and FIG. 17 are bottom views, and FIG. 18 and FIG. 19 are the cross-sectional views to which the under surface side was turned up.

As shown in FIG. 17-FIG. 20, a plurality of grooves 180 are formed in under surface 60b (plane of the side in contact with polishing pad 58) of retaining ring 60. Each groove 180 is formed so that the lower end of internal side surface (side surface at the side of an inner circumference) 60c and the lower end of 60d of external side surfaces (periphery side side surface) of retaining ring 60 may be connected. By forming groove 180 in under surface 60b of retaining ring 60, when doing CMP treatment of the semiconductor wafer 1, it can be promoted that the polishing liquid (slurry) supplied on polishing pad 58 is supplied to the polished surface of semiconductor wafer 1 in retaining ring 60 through groove 180 of retaining ring 60 from the outside of retaining ring 60. By forming groove 180 in retaining ring 60, it becomes possible to supply polishing liquid (slurry) uniformly in CMP treatment in the main surface (polished surface) of semiconductor wafer 1. Therefore, it can polish uniformly in the plane of a semiconductor wafer, and can suppress or prevent that the polish nonuniformity of a semiconductor wafer occurs.

Polishing head 54 contacts semiconductor wafer 1 by predetermined pressure at polishing pad 58 while rotating with retaining ring 60 and semiconductor wafer 1, and CMP treatment is performed. Groove 180 is formed in the direction which inclines to the normal line direction of the inner circumference (internal side surface 60c) or periphery (external side surface 60d) of under surface 60b of annular retaining ring 60 so that polishing liquid etc. may tend to pass through groove 180 of under surface 60b of rotating retaining ring 60.

In groove 180 of under surface 60b of retaining ring 60, screw hole 181 is formed as shown also in FIG. 16 and FIG. 19. Screw hole 181 has recess (first hole) 181a for accommodating head 170a of screw 170, and screw hole part (the second hole, the second recess) 181b by which it is formed in the bottom of recess 181a, and the screw thread is formed on the side wall (screw (female screw) is formed). Depth D₁ of recess 181a of screw hole 181 is larger than height H₁ of head 170a of screw 170 (D₁>H₁). Upper surface 170b of head 170a of screw 170 by which the screw stop was done in screw hole 181 can be prevented from projecting from under surface 60b of retaining ring 60 by this. When upper surface 170b of head 170a of screw 170 by which the screw stop was done in screw hole 181 has projected from under surface 60b of retaining ring 60 unlike this embodiment, head 170a of screw 170 may contact a polishing pad, and it may have a bad influence on a polishing pad. However, in this embodiment, since upper surface 170b of head 170a of screw 170 by which the screw stop was done to screw hole 181 has withdrawn to under surface 60b of retaining ring 60, it can be prevented that head 170a of screw 170 contacts a polishing pad. Depth D₁ of recess 181a of screw hole 181 is deeper than depth D₂ of groove 180 (D₁>D₂).

Screw hole part 181c is formed also in under surface 120b (plane of the side which attaches retaining ring 60) of diaphragm stop ring 120 of the position adjusted in screw hole part 181b of retaining ring 60. The screw thread is formed on the side wall of screw hole part 181c (the screw thread (female screw) is formed). Thread part 170c in which the screw thread (a male screw) is formed of screw 170 is further inserted (thrust, screwed) in screw hole part 181c of diaphragm stop ring 120 through screw hole part 181b of retaining ring 60, and the screw stop of the retaining ring 60 is done to diaphragm stop ring 120, and it is fixing.

2 gage pin 182 is formed as a position gap preventive measure of diaphragm stop ring 120 and retaining ring 60. For example, two hole parts (recess) 182a for gage pin 182 insertion are formed in under surface 120b of diaphragm stop ring 120. Hole part (recess) 182b for gage pin 182 insertion is formed also in upper surface 60a of retaining ring 60 in the position corresponding to this hole part 182a. When attaching retaining ring 60 to diaphragm stop ring 120, the end of gage pin 182 is first inserted in one side of hole parts 182a and 182b, for example hole part 182a of under surface 120b of diaphragm stop ring 120. So that the other end of gage pin 182 may be inserted in another side of hole parts 182a and 182b, for example so that the other end of gage pin 182 inserted in hole part 182a of diaphragm stop ring 120 may be inserted in hole part 182b of upper surface 60a of retaining ring 60, retaining ring 60 is arranged and positioned on diaphragm stop ring 120. And with screw 170, the screw stop of the retaining ring 60 is done to diaphragm stop ring 120, and it fixes.

In this embodiment, groove 180 is formed in under surface 60b of retaining ring 60, and screw hole 181 is formed in groove 180. That is, groove 180 is formed so that recess 181 a of screw hole 181 may be passed. By forming screw hole 181 in groove 180, a liquid (for example, liquid 59) is easily supplied to recess 181a of screw hole 181, and head 170a of screw 170, and it can be prevented that polishing liquid (slurry) solidifies at recess 181a of screw hole 181. Since pure water is supplied from nozzle 57c at platen 53c at the time of operation, and pure water is supplied from load cup 52 especially at the time of standby, this pure water flows through groove 180, and it can be prevented that polishing liquid (slurry) etc. solidifies at recess 181 a of screw hole 181.

When screw hole 181 is formed in regions other than groove 180 unlike this embodiment, polishing liquid collected on recess 181 a of screw hole 181 solidifies, the solid matter formed of this peels from recess 181a of screw hole 181 at the time of the CMP treatment of a semiconductor wafer, and it may have a bad influence on polish of a semiconductor wafer. To it, by having formed screw hole 181 in groove 180 formed in under surface 60b of retaining ring 60, the liquid which passes through groove 180 also passes recess 181a of screw hole 181, and it will be in the state where recess 181a of screw hole 181 always got wet, in CMP treatment by this embodiment. So, it can be prevented that polishing liquid (slurry) solidifies at recess 181a of screw hole 181, and can be prevented that the solidified polishing liquid has a bad influence on polish of a semiconductor wafer.

Under surface 120b of diaphragm stop ring 120 is more preferred when making flatness below into 30 μm. Hereby, when the screw stop of the retaining ring 60 is done to diaphragm stop ring 120 with screw 170, retaining ring 60 can be fixed stably and firmly to diaphragm stop ring 120.

Thus, in this embodiment, diaphragm 113 is clamped between diaphragm stop ring 120 and carrier plate 102. From the upper surface side of carrier plate 102, with screw 121, the screw stop of diaphragm stop ring 120 and the carrier plate 102 is done, and they are fixed. The screw stop of the retaining ring 60 is done to this diaphragm stop ring 120 with screw 170 from a lower part (under surface 60a side of retaining ring 60), and it is fixed.

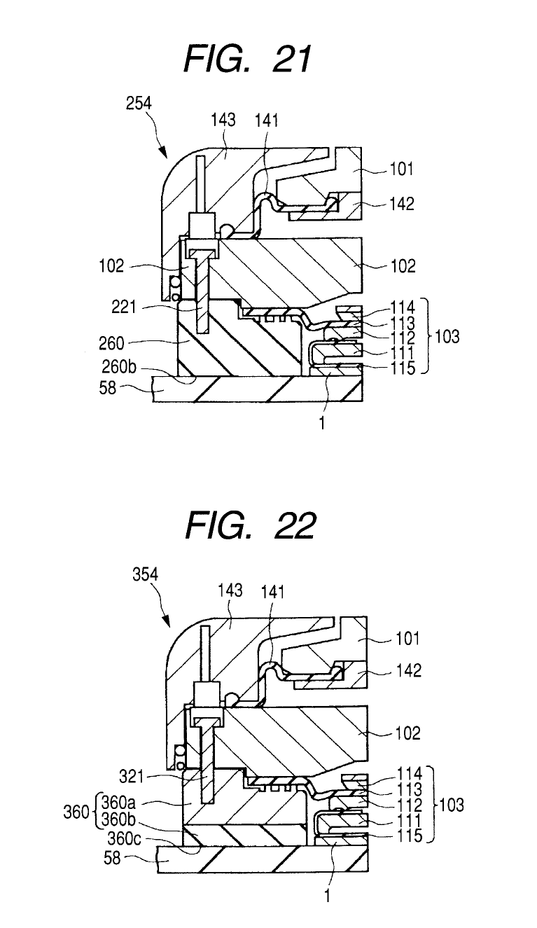

FIG. 21 is a principal part cross-sectional view showing polishing head 254 of the first comparative example that the present inventor examined. The region corresponding to FIG. 15 is shown in FIG. 21. In polishing head 254 of FIG. 21, the outer edge of diaphragm 113 is clamped between retaining ring 260 (retaining ring 260 of the first comparative example) of the annular shape which includes a resin material, and carrier plate 102, without using diaphragm stop ring 120. From the upper surface side of carrier plate 102, with screw 221, the screw stop of the retaining ring 260 is done to carrier plate 102, and it is being fixed to it. Other structures are almost the same as that of polishing head 54 of this embodiment, and the explanation is omitted here.

In polishing head 254 of the first comparative example shown in FIG. 21, it is fixing directly on both sides of diaphragm 113 which includes elastic bodies, such as a rubber material, between retaining ring 260 which includes a resin material, and carrier plate 102. For this reason, according to a neglect state, surface deformation of retaining ring 260 may occur, the grinding rate of the edge part of a semiconductor wafer may be affected, and the uniformity of the polishing quantity of a semiconductor wafer may not be stabilized. For example, at the time of standby (before processing), it deforms so that under surface 260b of retaining ring 260 may turn to an outside under the influence of diaphragm 113 which includes elastic bodies, such as a rubber material. At the time of processing of CMP treatment, with the pressure from polishing pad 58, it deforms so that under surface 260b of retaining ring 260 may turn to the inside. Thus, the surface state of retaining ring 260 is not stabilized in polishing head 254 of the first comparative example. So, the surface state (for example, angle of gradient of under surface 260b of retaining ring 260 to the front surface of a polishing pad) of retaining ring 260 changes whenever it repeats a standby state and a processing state, the grinding rate of the edge part of a semiconductor wafer may be affected, and the uniformity of the polishing quantity of a semiconductor wafer may not be stabilized. This reduces the manufacturing yield of a semiconductor device and increases the manufacturing cost of a semiconductor device.

FIG. 22 is a principal part cross-sectional view showing polishing head 354 of the second comparative example that the present inventor examined. The region corresponding to FIG. 15 is shown in FIG. 22. In polishing head 354 of FIG. 22, without using diaphragm stop ring 120, annular retaining ring 360 (retaining ring 360 of the second comparative example) which includes first portion 360a that includes material which has the rigidity of stainless steel etc., and second portion 360b that includes a resin material and was adhered on first portion 360a is used. The outer edge of diaphragm 113 is clamped between this first portion 360a of retaining ring 360 and carrier plate 102. From the upper surface side of carrier plate 102, with screw 321, the screw stop of the retaining ring 360 is done to carrier plate 102, and it is being fixed to it. Since other structures are the same as that of polishing head 54 of this embodiment almost, the explanation is omitted here.

In polishing head 354 of the second comparative example shown in FIG. 22, retaining ring 360 which pasted up with the binder first portion 360a that includes stainless steel etc., and second portion 360b that includes a resin material, and was unified is formed. The screw stop of this retaining ring 360 is done to carrier plate 102. In the second comparative example, it is fixing on both sides of diaphragm 113 which includes elastic bodies, such as a rubber material, between first portion 360a of the retaining rings 360 that includes stainless steel etc., and carrier plate 102. Therefore, compared with the first comparative example that sandwiched diaphragm 113 between retaining ring 260 which includes a resin material, and carrier plate 102, the clamp state of diaphragm 113 is not changed easily. Even if it repeats a standby state and a processing state, the surface state (for example, angle of gradient of under surface 360c of second portion 360b of retaining ring 360 to the front surface of polishing pad 58) of retaining ring 360 is not changed easily. The uniformity of the polishing quantity of a semiconductor wafer can be stabilized.

However, in the second comparative example, when second portion 360b that includes a resin material of retaining ring 360 is worn out by performing CMP treatment of a plurality of semiconductor wafers, exchange of retaining ring 360 is needed. Since first portion 360a and second portion 360b are pasted up and unified with the binder, it is necessary to exchange the whole retaining ring 360 which includes first portion 360a and second portion 360b. Whenever it exchanges retaining ring 360, the clip condition of diaphragm 113 by first portion 360a of retaining ring 360 and carrier plate 102 may change, and the polishing rate of the edge part of a semiconductor wafer may be affected. For this reason, after exchanging for new retaining ring 360, by deciding the conditions of retaining ring 360, etc., before starting the CMP treatment of a product wafer (semiconductor wafer for manufacturing a semiconductor device), it is necessary to carry out to adjust or confirm the polishing rate of the edge part of a semiconductor wafer. This reduces the operating ratio of a CMP device and increases the manufacturing cost of a semiconductor device. When second portion 360b that includes a resin material is worn out, it is necessary to exchange the whole retaining ring 360 which includes first portion 360a and second portion 360b. Therefore, the unit price of replacement parts (retaining ring 360) will become high, and this will also increase the manufacturing cost of a semiconductor device.

Comparing with it, in this embodiment, diaphragm 113 is clamped between diaphragm stop ring 120 which includes material (metallic material) which has the rigidity of, for example stainless steel etc., and carrier plate 102, the screw stop of diaphragm stop ring 120 and the carrier plate 102 is done with screw 121 from the upper surface side of carrier plate 102, and it fixes firmly, and the screw stop of the retaining ring 60 which includes a resin material is done to this diaphragm stop ring 120 with screw 170 from a lower part (under surface 60a side of retaining ring 60), and it is fixing to it firmly. Not pinching diaphragm 113 between retaining ring 60 which includes a resin material, and diaphragm stop ring 120, diaphragm 113 is clamped between diaphragm stop ring 120 harder (mechanical strength is high) than retaining ring 60 and carrier plate 102, and retaining ring 60 is directly fixed on under surface 120b of diaphragm stop ring 120 where flatness is good. Therefore, retaining ring 60 can be firmly and stably fixed in diaphragm stop ring 120 and carrier plate 102. For this reason, deformation of the resin front surface (polishing pad contact part) of retaining ring 60 cannot occur, but the uniformity of the polishing quantity of a semiconductor wafer can be stabilized. For example, the clamp state of diaphragm 113 does not change easily, and at the time of standby (before processing) and processing of CMP treatment, the surface state (for example, angle of gradient of under surface 60b of retaining ring 60 to the front surface of polishing pad 58) of retaining ring 60 cannot be changed, but the surface state of retaining ring 60 can be stabilized. Therefore, even if it repeats a standby state and a processing state, the uniformity of the polishing quantity of a semiconductor wafer can be stabilized. Hereby, the manufacturing yield of a semiconductor device is improved and the manufacturing cost of a semiconductor device can be reduced.

Exchange of retaining ring 60 is needed in wearing out retaining ring 60 which includes a resin material by performing CMP treatment of a plurality of semiconductor wafers. However, in this embodiment, the screw stop of the retaining ring 60 is done to diaphragm stop ring 120 with screw 170 from the lower part (under surface 60b side), and retaining ring 60 can be exchanged only by removing screw 170. For this reason, retaining ring 60 can be exchanged promptly and easily, and the workability of exchange of retaining ring 60 can be improved. Only retaining ring 60 can be removed and exchanged by removing screw 170, and it is not necessary to remove diaphragm stop ring 120 at the time of retaining ring 60 exchange. For this reason, even if it exchanges retaining ring 60, the clip condition of diaphragm 113 by diaphragm stop ring 120 and carrier plate 102 does not change. Therefore, even if it exchanges retaining ring 60, the surface state of retaining ring 60 is not changed. Therefore, after exchange of retaining ring 60, CMP treatment can be started promptly and the uniformity of the polishing quantity of a semiconductor wafer can be stabilized. Hereby, the operating ratio of a CMP device can be improved and the manufacturing cost of a semiconductor device can be reduced. When retaining ring 60 is worn out, what is necessary is to exchange only retaining ring 60 which includes a resin material, and exchange of diaphragm stop ring 120 which is metal parts is unnecessary. Therefore, the unit price of replacement parts (retaining ring 60) can be made cheap, and this can also be contributed to reduction of the manufacturing cost of a semiconductor device.

In this embodiment, groove 180 is formed in under surface 60b of retaining ring 60, and screw hole 181 is formed in groove 180. That is, groove 180 is formed so that recess 181 a of screw hole 181 may be passed. By forming screw hole 181 in groove 180, a polishing liquid easily becomes to be supplied to recess 181a of screw hole 181, and head 170a of screw 170. It can be prevented that polishing liquid (slurry) solidifies at recess 181a of screw hole 181. Hereby, it can be prevented that the solidified polishing liquid has a bad influence on polish of a semiconductor wafer. Therefore, the manufacturing yield of a semiconductor device is improved and the manufacturing cost of a semiconductor device can be reduced.

### EMBODIMENT 2

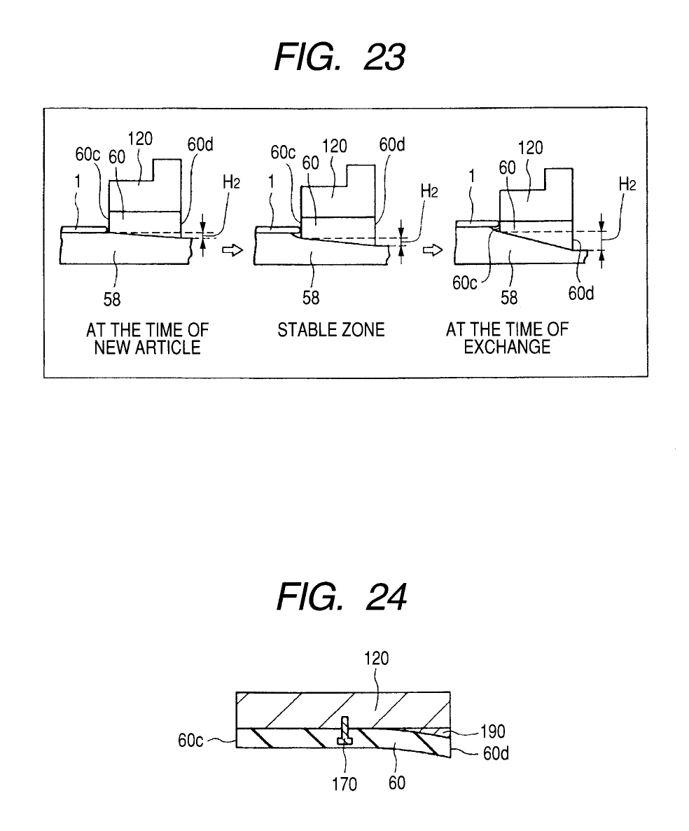

FIG. 23 is an explanatory diagram (cross-sectional view) showing the abrasion model of retaining ring 60 which includes a resin material. At the time of the new article immediately after exchanging retaining ring 60 (it corresponds at the time of the new article of FIG. 23), under surface 60b (plane of the side in contact with polishing pad 58) of retaining ring 60 is almost flat. The flatness H₂ is smaller than for example, 30 μm (H₂<30 μm). When CMP treatment of many semiconductor wafers is done, under surface 60b of retaining ring 60 is also polished together, and is worn out. Abrasion of retaining ring 60 of the inner periphery side is early rather than that of the peripheral part side of retaining ring 60, and under surface 60b of retaining ring 60 comes to incline. While the angle of gradient of under surface 60b of retaining ring 60 is small, CMP treatment of semiconductor wafer 1 can be stably performed (it corresponds at the time of the stability of FIG. 23). For example, when flatness H₂ of under surface 60b of retaining ring 60 is about 30-50 μm (30 μm≦H₂≦50 μm), CMP treatment of semiconductor wafer 1 can be stably performed. However, when CMP treatment of the semiconductor wafer of a large number further is performed, and the angle of gradient of under surface 60b of retaining ring 60 becomes large, for example when flatness H₂ of under surface 60b of retaining ring 60 becomes larger than 50 μm (H₂>50 μm), the face pressure of polishing pad 58 near the end portion of semiconductor wafer 1 becomes high, and a polishing rate becomes large too much at the end portion of semiconductor wafer 1 (it becomes edge-first). Therefore, it becomes impossible to stably perform CMP treatment of a semiconductor wafer, and exchange of retaining ring 60 is needed (it corresponds at the time of exchange of FIG. 23).

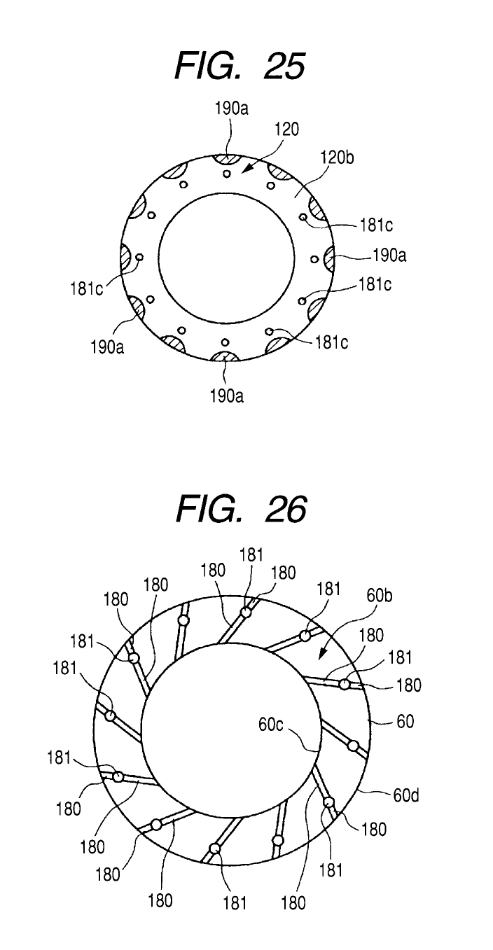

According to the analyses of the present inventor, when CMP treatment of many semiconductor wafers is done, it turned out that polishing liquid (slurry) may invade between the member which did the screw stop of the retaining ring 60 (here diaphragm stop ring 120), and retaining ring 60 by uneven wear, a warp, etc. of retaining ring 60 which includes a resin material. FIG. 24 is a cross-sectional view (explanatory diagram) showing notionally the state where polishing liquid 190 invaded between diaphragm stop ring 120 and retaining ring 60. FIG. 25 is a plan view (explanatory diagram) showing under surface 120b of diaphragm stop ring 120 when removing retaining ring 60, after performing CMP treatment to many semiconductor wafers.

The polishing liquid supplied on polishing pad 58 from nozzle 57 runs polishing pad 58 upper part from the outside of retaining ring 60 to the inside, and is supplied to the polished surface of semiconductor wafer 1 currently held inside retaining ring 60. Therefore, as shown in FIG. 24, polishing liquid 190 trespasses upon the clearance between retaining ring 60 and diaphragm stop ring 120 easilier at the periphery side (external side wall 60d side) than the inner circumference side (internal side surface 60c side) of retaining ring 60. For this reason, when retaining ring 60 is removed, as shown in FIG. 25, the remains 190a of polishing liquid will generate in the peripheral part side of under surface 120b of diaphragm stop ring 120. As shown in FIG. 24, when polishing liquid 190 trespasses upon the clearance at the side of the peripheral part between retaining ring 60 and diaphragm stop ring 120, since it acts so that the inclination of under surface 60b of retaining ring 60 may become large, and the shift from a stable zone to the time of exchange of FIG. 23 is brought forward, the replacement life (lifetime in which CMP treatment is possible) of retaining ring 60 may become short.

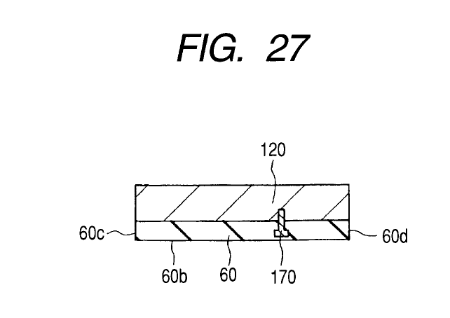

FIG. 26 is a plan view (bottom view) of retaining ring 60 used by this embodiment, and FIG. 27 is the schematic cross-sectional view. FIG. 26 corresponds to the FIG. 17 of the above-mentioned embodiment. In FIG. 27, in order to simplify an understanding, illustration of groove 180 is omitted.

In above-mentioned Embodiment 1, a plurality of grooves 180 were formed in under surface 60b (plane of the side in contact with a polishing pad) of retaining ring 60, and screw hole 181 was formed near the center of each groove 180. A plurality of grooves 180 are formed in under surface 60b (plane of the side in contact with a polishing pad) of retaining ring 60 in this embodiment. Rather than the center of each groove 180, screw hole 181 is formed in the peripheral part side (an outside, the external side wall 60d side), and the screw stop is done to diaphragm stop ring 120 with screw 170 in this screw hole 181. Since other structures are the same as that of above-mentioned Embodiment 1 almost, the explanation is omitted here.

In this embodiment, as mentioned above, a plurality of grooves 180 are formed in under surface 60b of retaining ring 60, screw hole 181 is formed in near peripheral part rather than the center of each groove 180, and the screw stop is done to diaphragm stop ring 120 with screw 170 in this screw hole 181. Therefore, it becomes difficult to generate a clearance between retaining ring 60 and diaphragm stop ring 120 at the peripheral part side of retaining ring 60, and can prevent that polishing liquid invades there. For this reason, it can prevent that retaining ring 60 warps and the replacement life (lifetime in which CMP treatment is possible) of retaining ring 60 can be lengthened.

Surface coating, such as silicon, can also be given to the member to which the screw stop of the retaining ring 60 is done, here to under surface 120b of diaphragm stop ring 120 (the plane of the side which attaches retaining ring 60, the plane of the side which faces retaining ring 60 and contacts). It can be prevented more surely by this that polishing liquid invades between retaining ring 60 and diaphragm stop ring 120, and the replacement life (lifetime in which CMP treatment is possible) of retaining ring 60 can be lengthened more.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

### INDUSTRIAL APPLICABILITY

It is effective in the application to the manufacturing technology of a semiconductor device which has a step which does Chemical Mechanical Polishing of the semiconductor wafer.

1. A fabrication method of a semiconductor device, comprising a step of:
doing Chemical Mechanical Polishing of a semiconductor wafer where the semiconductor wafer is held in a wafer holding part with a retaining ring which did a screw stop to the wafer holding part from a lower part, and which includes a resin material;
wherein a groove is formed in an under surface of the retaining ring, and a retaining ring with which a screw hole deeper than a depth of the groove is formed in the groove portion in order to do a screw stop of the retaining ring is used.

2. A fabrication method of a semiconductor device according to claim 1, wherein
the groove is formed in a direction which inclines to a normal line direction of a periphery or an inner circumference of the retaining ring.

3. A fabrication method of a semiconductor device according to claim 1, wherein
the screw hole is formed in a peripheral part side of the retaining ring rather than a central part of the groove.

4. A fabrication method of a semiconductor device according to claim 1, wherein
the screw hole has a first hole for accommodating a head of a screw for doing a screw stop of the retaining ring, and a second hole which is formed in a bottom of the first hole, and whose screw thread is formed in a side wall, and depth of the first hole is larger than height of the head of the screw.

5. A fabrication method of a semiconductor device according to claim 4, wherein
the groove is formed so that the groove may pass through the first hole of the screw hole.

6. A fabrication method of a semiconductor device, comprising a step of:
using a grinding apparatus of single wafer processing provided with a plurality of turn tables, a wafer holding part holding a semiconductor wafer moving the turn tables one by one, and performing Chemical Mechanical Polishing processing of a semiconductor wafer where the semiconductor wafer is held in the wafer holding part with a retaining ring which did a screw stop to the wafer holding part from a lower part, which includes a resin material, and with which a groove is formed in an under surface of the resin material, and a screw hole deeper than a depth of the groove is formed in the groove portion in order to do a screw stop of the resin material to the wafer holding part.

7. A fabrication method of a semiconductor device according to claim 6, wherein
a cleaning treatment of the semiconductor wafer is consistently performed after the Chemical Mechanical Polishing processing.

8. A fabrication method of a semiconductor device, comprising a step of:
doing Chemical Mechanical Polishing of a semiconductor wafer where the semiconductor wafer is held in a wafer holding part with a retaining ring which did a screw stop to the wafer holding part from a lower part, and which includes a resin material;
wherein a diaphragm is fixed to the wafer holding part by a diaphragm holddown member, and a screw stop of the retaining ring is done to an under surface of the diaphragm holddown member from a lower part.

9. A fabrication method of a semiconductor device according to claim 8, wherein
the diaphragm holddown member has an annular form.

10. A fabrication method of a semiconductor device according to claim 8, wherein
the semiconductor wafer is pushed against a polishing pad by pressurizing a space sealed with the diaphragm.

11. A fabrication method of a semiconductor device according to claim 8, wherein
the diaphragm holddown member includes a metallic material.

12. A fabrication method of a semiconductor device according to claim 8, wherein
the diaphragm holddown member includes stainless steel.

13. A fabrication method of a semiconductor device according to claim 8, wherein
the diaphragm includes an elastic membrane.

14. A fabrication method of a semiconductor device according to claim 8, wherein
a groove is formed in an under surface of the retaining ring, and a screw hole for doing a screw stop of the retaining ring is formed in the groove.

15. A fabrication method of a semiconductor device, comprising a step of:
doing Chemical Mechanical Polishing of a semiconductor wafer where the semiconductor wafer is held in a wafer holding part with a retaining ring which did a screw stop to the wafer holding part from a lower part, and which includes a resin material;
wherein an elastic membrane is fixed to the wafer holding part by an annular metal member, and a screw stop of the retaining ring is done to an under surface of the metal member from a lower part.

16. A fabrication method of a semiconductor device according to claim 15, wherein
the semiconductor wafer is pushed against a polishing pad by pressurizing a space sealed by the elastic membrane.

17. A fabrication method of a semiconductor device according to claim 15, wherein
a groove is formed in an under surface of the retaining ring, and in the groove a screw hole deeper than a depth of the groove is formed at the groove portion in order to do a screw stop of the resin material to the wafer holding part.
